(19) United States
(12) Patent Application Publication
(10) Pub. No.: US 2009/0133731 A1
(43) Pub. Date: May 28, 2009

(54) CRISS-CROSSED AND COALIGNED CARBON NANOTUBE-BASED FILMS

(75) Inventors: Haim Grebel, Livingston, NJ (US); Shamim Mirza, Irvine, CA (US)

Correspondence Address: GIBSON & DERNIER L.L.P., 900 ROUTE 9 NORTH, SUITE 504, WOODBRIDGE, NJ, 07095, US

(73) Assignee: New Jersey Institute of Technology, Newark, NJ (US)

(21) Appl. No.: 12/262,906

(22) Filed: Oct. 31, 2008

Related U.S. Application Data
(60) Provisional application No. 60/984,491, filed on Nov. 1, 2007.

(51) Int. Cl. H01L 37/00; B32B 5/12; H01L 21/26; B82B 1/00; B82B 3/00

(52) U.S. Cl. 136/200; 428/113; 438/795; 977/742; 977/932; 977/842; 257/E21.328

(57) ABSTRACT

Devices including nano-junctions made between aligned functionalized carbon nanotubes, and methods of aligning functionalized carbon nanotubes for the purpose of fabricating either coaligned or criss-crossed p-n junctions. Devices, such as thermoelectric devices, may be formed of a plurality of n-type carbon nanotubes forming a film and/or a plurality of p-type carbon nanotubes forming a film. Methods of making a criss-crossed p-n nanojunction device include the steps of functionalizing a carbon nanotube to create a p-type tube, functionalizing a carbon nanotube to create an n-type tube, applying an RF field to align nanotubes of a given p- or n-type, and orienting nanotubes of different types cross-wise relative to each other to achieve criss-crossed p-n nanojunctions.

### CROSS-REFERENCE TO RELATED APPLICATIONS

This application claims the benefit of U.S. Provisional Patent Application Ser. No. 60/984,491, filed Nov. 1, 2007, the entirety of which is incorporated herein by reference.

### FIELD OF THE INVENTION

The invention relates to carbon nanotubes and in particular devices including nano-junctions made between carbon nanotubes and methods for making same.

### BACKGROUND OF THE INVENTION

Carbon nanotubes have captured the imagination of many researchers owing to their unique quasi one-dimensional characteristics. Their properties have inspired interest in potential applications such as nanosensors (J. H. Hafner, C. L. Cheung, T. H. Oosterkamp, and C. M. Lieber, J. Phys. Chem. B, 105, 744 (2001)); optoelectronics (G. Fanchini, H. E. Unalan, and M. Chhowalla, Appl. Phys. Lett., 88, 191919-1 (2006)); and thermionics (J. Hone, M. C. Llaguno, N. M. Names, A. T. Johnson, J. E. Fischer, D. A. Walters, M. J. Casavant, J. Schmidt, and, R. E. Smalley, Appl. Phys. Lett., 77, 666 (2000)). Carbon nanotubes have already been used as composite fibers in polymers to improve their mechanical, thermal and electrical properties of the bulk product. Carbon nanotubes are easy to functionalize.

Because of the symmetry and unique electronic structure of graphite, the structure of a carbon nanotube strongly affects its electrical properties. Due to their nanoscale dimensions, electron transport in carbon nanotubes takes place through quantum effects and will only propagate along the axis of the tube, hence, carbon nanotubes are frequently referred to as “one-dimensional”.

The anisotropic nature of individual tubes has triggered studies on resonant quantum tunneling as a function of gate bias (Konstantin K. Likharev, Proc. IEEE, 87, 606 (1999); M. J. Biercuk, N. Mason, J. Martin, A. Yacoby, and C. M. Marcus, PRL 94, 026801 (2005); and C. Zhou, J. Kong, E. Yenilmez and H. Dai, Science, 290, 1552 (2000)). Yet, electronic scattering in the above mentioned studies were always induced along the (individual) tube axis. In contrast, when a junction is formed between two crossed and functionalized tubes, electronic scatterings are made in perpendicular directions, and therefore, require a strong coupling mechanism between the initial and final current states. Crossed structures have been realized by functionalized quantum wires yet did not exhibit stair behavior as in the present case (X. Duan, Y. Huang, Y. Cui, J. Wang and C. Lieber, Nature, 409, 66 (2001)).

### SUMMARY OF THE INVENTION

The present inventors have developed devices including nano-junctions made between aligned functionalized carbon nanotubes, and methods of aligning functionalized carbon nanotubes for the purpose of fabricating either co-aligned or criss-crossed p-n junctions. The present inventors have found, surprisingly, that a network of criss-crossed diodes exhibits novel current-voltage staircase curves at room and liquid nitrogen temperatures as compared to randomly oriented nanotubes and coaligned tubes. The network of criss-crossed diodes also reflected superior current-voltage staircase curves compared to the I-V curves of criss-crossed and coaligned contacts between same-type tubes. The bias values, at which current steps occur, are separated by multiple of 0.067 V.

Functionalized carbon nanotubes in accordance with the present techniques may be biased with optical or bio-signals and the change in the junction characteristics may be detected.

In one embodiment a device in accordance with the present invention comprises at least one n-type carbon nanotube disposed cross-wise relative to at least one p-type carbon nanotube, the n-type and p-type carbon nanotubes forming at least one nano-junction therebetween. Such a device may include a plurality of n-type carbon nanotubes and/or a plurality of p-type carbon nanotubes.

In a further embodiment devices in accordance with the present invention may comprise a plurality of n-type carbon nanotubes forming a film and/or a plurality of p-type carbon nanotubes forming a film.

In yet a further embodiment devices in accordance with the present invention may comprise input and output terminal(s) and a contact.

In still a further embodiment the carbon nanotubes may include one or more functionalizing agents, such as but not limited to polyvinylpyrrolidone or polyethylenimine.

In a further embodiment a device in accordance with the present invention may be a bioelectronic device, an optoelectronic device or the like.

In at least one aspect the present invention provides a method of producing either coaligned or criss-crossed p-n junctions including the steps of functionalizing single-wall carbon nanotubes (SWCNT) to create either p- or n-type tubes, applying an RF field to align the tubes of a given p- or n-type, and overlaying films of different types (p and n) to achieve either co-aligned or criss-crossed p-n junctions.

In one aspect methods in accordance with the present invention employ novel frequencies for the applied electric field.

In still a further embodiment the present invention provides a method of making a criss-crossed p-n nanojunction comprising the steps of functionalizing a carbon nanotube to create a p-type tube, functionalizing a carbon nanotube to create an n-type tube, applying an RF field to align nanotubes of a given p- or n-type, and orienting nanotubes of different types cross-wise relative to each other to achieve criss-crossed p-n nanojunctions.

In yet a further embodiment the present invention provides methods comprising forming functionalized p-type carbon nanotubes into a p-type film, forming functionalized n-type carbon nanotubes into an n-type film, and orienting one of the films over the other such that the carbon nanotubes of the respective films are “criss-crossed”, i.e., cross-wise, with respect to one another.

In still yet a further embodiment the present invention provides methods for forming a network of criss-crossed diodes. In yet another aspect of the invention, the methods of the present invention facilitate identification of carbon nanotube bridges before and after interconnection. Such use of functionalized nanotubes allows for the presently disclosed nanotubes to be biased with optical or bio-signals so that the change in junction characteristics pursuant to the attached signals can be detected. As such, the present invention may be employed in various suitable applications such as but not limited to optoelectronic and bioelectronic devices.

In yet a further embodiment, thermoelectric devices are provided having at least one n-type carbon nanotube disposed cross-wise with respect to at least one p-type carbon nanotube, the n-type and p-type carbon nanotubes forming at least one nano-junction therebetween. In another embodiment, thermoelectric segmented devices are provided having a first segment composed of aligned n-type or p-type SWCNT film and at least one other segment composed of n-type or p-type SWCNT film, wherein the segments are coaligned with respect to each other and interface one another along a common region. The coaligned segments may be made of the same type SWCNT film.

Other suitable applications will be apparent to those having skill in the art.

### BRIEF DESCRIPTION OF THE DRAWINGS

A more complete understanding of the invention may be obtained by reading the following description of specific illustrative embodiments of the invention in conjunction with the appended drawings in which:

FIG. 1 (a) depicts a schematic view of a circuit wherein p- and n-type carbon nanotubes are criss-crossed in accordance with at least one aspect of the present invention.

FIG. 1(b) depicts a SEM picture of aligned tubes in accordance with at least one aspect of the present invention.

FIG. 2 is a graphical depiction of Raman spectra of the carbon nanotube G-line as well as (in the inset) the signal-to-noise ratio (SNR) of polarized Raman scattering in accordance with at least one aspect of the present invention.

FIG. 3 is a graphical depiction of thermoelectricity developed for aligned p-type SWCNT samples, indicating thermoelectric characteristics varied when measured either in parallel or, in cross-wise direction to the film orientation in accordance with at least one aspect of the present invention.

FIG. 3(a) is a graphical depiction of TE curves for randomly oriented MWCNT p-n junctions laid side-by-side, the up and down curves depicting temperature scans. The inset depicts the corresponding I-V curve.

FIG. 3(b) depicts TE properties of SWCNT, p-type and p-n junctions wherein randomly dispersed and aligned samples are shown. Indicated are the overall resistance values. Both up and down curves depict temperature scans.

FIG. 4(a) is a graphical depiction of a log plot of I-V curves for p-n nano-junctions for p- and n-type SWCNT aligned in coalignment in accordance with at least one aspect of the present invention. The inset shows the entire I-V curve.

FIG. 4 (b) is a graphical depiction of a log plot of I-V curves for p-n nano-junctions for p- and n-type SWCNT films aligned cross-wise with respect to one another in accordance with at least one aspect of the present invention. The inset shows the entire I-V curve.

FIG. 4 (c) is a graphical representation of a log plot and linear plot in up and down voltage ramp indicating Negative Differential Resistance for crisscrossed p-n junctions in accordance with at least one aspect of the present invention.

FIG. 4 (d) is a graphical representation of a relatively thin (<1 micron) sample with hysteresis reversed in accordance with at least one aspect of the present invention.

FIG. 4 (e) is a graphical depiction of a log plot of I-V curves for p-n nano-junctions for p- and n-type SWCNT films indicating stair position as a function of an integral number of steps in accordance with at least one aspect of the present invention.

FIGS. 5 (a) and 5 (b) are graphical representations of I-V curves of crisscrossed and coaligned junctions immersed in liquid nitrogen in accordance with at least one aspect of the present invention.

FIG. 6 is a graphical depiction of I-V for single and criss-crossed n-type layers at room and liquid nitrogen (LN) temperatures.

FIG. 7 depicts a schematic view of crisscrossed tubes with terminals in accordance with at least one aspect of the present invention.

FIG. 8 depicts a qualitative current-voltage plot I=(A+BT)I_{D}. A=1; B=5; C=0.05 eV; E₀=0.067 eV; ηV_{T}=0.1 V; I₀=10⁻⁶ A in accordance with at least one aspect of the present invention.

It should be noted that the appended drawings illustrate only typical embodiments of this invention and are therefore not to be construed as limiting of its scope, for the invention may admit to other equally effective embodiments. Where possible, identical reference numerals have been inserted in the figures to denote identical elements.

### DETAILED DESCRIPTION OF THE PREFERRED EMBODIMENTS

In the following description, for purposes of explanation, specific numbers, materials and configurations are set forth in order to provide a thorough understanding of the invention. It will be apparent, however, to one having ordinary skill in the art that the invention may be practiced without these specific details. In some instances, well-known features may be omitted or simplified so as not to obscure the present invention. Furthermore, reference in the specification to phrases such as “one embodiment” or “an embodiment” means that a particular feature, structure or characteristic described in connection with the embodiment is included in at least one embodiment of the invention. The appearances of phrases such as “in one embodiment” in various places in the specification are not necessarily all referring to the same embodiment.

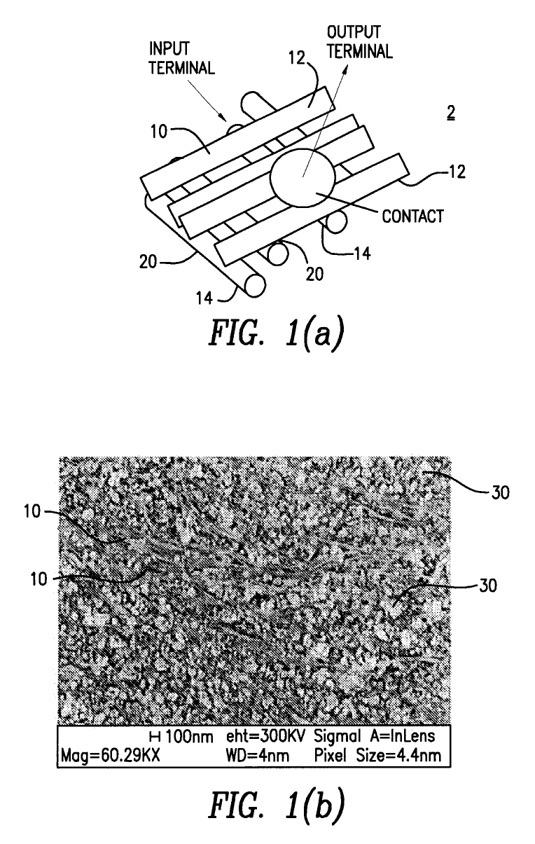

Now referring to FIG. 1, in one embodiment a device 2 includes carbon nanotubes 10, an input terminal, and output terminal and a contact. N-type carbon nanotubes 12 are disposed cross-wise over p-type carbon nanotubes 14, forming nano-junctions 20 between nanotubes 12 and 14.

Carbon nanotubes 10 are preferably single-wall carbon nanotubes (SWCNT) formed in accordance with known techniques. The SWCNT may be functionalized using any suitable functionalizing agent such as but not limited to polyvinylpyrrolidone (PVP), polyethylenimine (PEI) or the like.

Devices 2 may comprise a plurality of n-type carbon nanotubes 12 forming a film and/or a plurality of p-type carbon nanotubes 14 forming a film.

Device 2 may be a bioelectronic device, an optoelectronic device or the like.

In one embodiment a method is provided of producing either coaligned or criss-crossed p-n junctions including the steps of functionalizing single-wall carbon nanotubes (SWCNT) to create either p- or n-type tubes, applying an RF field to align the tubes of a given p- or n-type type, and overlaying films of different types (p and n) to achieve either coaligned or criss-crossed p-n junctions. The frequency of the applied field is typically in the range of between 500 Kilo Hertz and 20 Mega Hertz, preferably between 10 Mega Hertz and 15 Mega Hertz.

In a preferred embodiment a method of making a criss-crossed p-n nanojunction includes the steps of functionalizing a carbon nanotube to create a p-type tube, functionalizing a carbon nanotube to create an n-type tube, applying an RF field to align nanotubes of a given p- or n-type, and orienting nanotubes of different types cross-wise relative to each other to achieve criss-crossed p-n nanojunctions.

In another preferred embodiment a method includes forming functionalized p-type carbon nanotubes into a p-type film, forming functionalized n-type carbon nanotubes into an n-type film, and orienting one of the films over the other such that the carbon nanotubes of the respective films are criss-crossed with respect to one another.

In another embodiment the present invention provides methods for forming a network of criss-crossed diodes.

In yet another embodiment, the methods of the present invention facilitate identification of carbon nanotube bridges before and after interconnection.

The foregoing embodiments are further described with reference to the following experiments and examples.

### EXPERIMENTS AND EXAMPLES

Single-wall carbon nanotubes (SWCNT), mostly with a diameter of 1.37 nm, and 60-70% purity, were purchased from CarboLex Co., purified according to well established techniques as disclosed in Liu, J. et al., Science, 280, 1253 (1998) and dispersed by use of a sonicator in ethanol. The SWCNT were functionalized with a functionalizing agent, either poly(vinylpyrrolidone) (PVP) of molecular weight (MW) 40,000 or poly(ethylenimine) (PEI) of MW 1,000,000, in order to achieve wrapped tubes either in small bundles or as individuals, p- or n-type, respectively. After several trials, the ratio of the polymer and SWCNT was fixed at 2:1 for both cases resulting in a uniform and low resistive film. The film thickness was several micrometers for all cases. Wrapping was helpful in minimizing tube agglomeration. There were indications that the wrapping process reduced the amount of suspended metallic tubes: empirically it was found that the sediment contained an unusual large amount of wrapped metallic tubes. Low leakage currents in reverse biased diodes corroborated these findings. The type of each film, either p-type or n-type, was assessed by its thermoelectric properties. The SWCNT were aligned in a RF field (13.6 MHz) at power levels exceeding 100 W between electrodes at 7 mm apart while in suspension. A typical sample size was 25×7 mm². The films were air dried.

Now referring to FIG. 1(a), a schematic of a device 2 is depicted wherein the p-type nanotubes 14 and n-type carbon nanotubes 12 are criss-crossed forming nano-junctions 20. The device 2 was made by laying successive layers of p- and n-type nanotube films on top of each other. The films were cast from a suspension on a glass plate (2.5 cm×0.8 cm). The overall film thickness was several micrometers for all cases. Now referring to FIG. 1(b), it is clearly shown the structures 10 of FIG. 1(a) exhibited tube orientation at the nano-scale. The bright regions 30 are dried-out polymer. A review of multiple SEM pictures was undertaken wherein each picture was divided into pixels and the orientation of the tube or tube segment with respect to a reference direction was assessed. Statistics were plotted for all oriented tubes and it was determined that 90% of the tubes were aligned along the applied field direction within ±11.25° range.

Films aligned to a lesser extent exhibited I-V characteristics typical of random films. Resistance values in direction perpendicular to the tube axis were typically larger, by a factor of 2-4, compared to resistance along the tubes' axis. The type of each film, either p-type or n-type was assessed by its thermoelectric properties. One end of the sample was placed on a hot plate while the other end was resting on a post at room temperature. One of the leads was made of copper wire, which was attached under the film to the hot end using silver epoxy paint. The lead for the cooler end was made of graphite. The absolute thermoelectric power of the copper wire (+2.34 μV/° C.) was not considered. The direction of the developed voltage is indicative of the film type. In general, thermoelectric characteristics varied when measured either in parallel or, in perpendicular direction to the film orientation. The developed TE voltage was larger when assessed perpendicularly to the direction of tubes' axis. The complete TE data will be reported elsewhere.

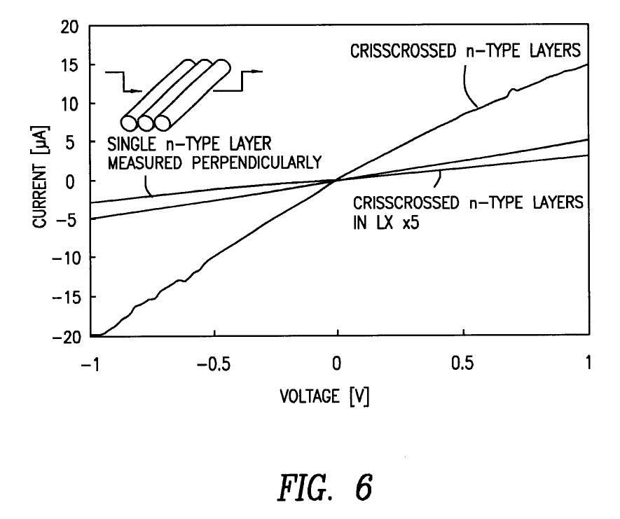

Additional assessment of individual films and junction were obtained by current-voltage (I-V) measurements. Contacts to films were ohmic (see for example FIG. 6) with the top electrode pressing the films below them.

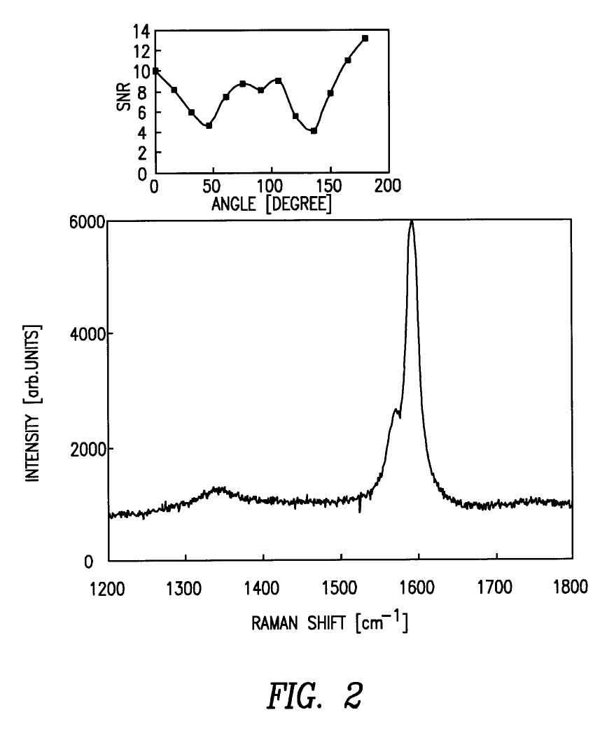

Polarized Raman spectroscopy was used to identify the existence of oriented tubes. The Raman spectra were characteristics of semiconductive SWCNT (Jorio, A.; Souza Filho, A. G.; Dresselhaus, G.; Dresselhaus, M. S.; Swan, A. K.; Ünlü, M. S.; Goldberg, B. B.; Pimenta, M. A.; Hafner, J. H.; Lieber, C. M.; Saito, R. Phys. Rev. B, 65, 155412 (2002)). Now referring to FIG. 2, Raman spectra of the CNT G-line as well as the signal-to-noise ratio (SNR) of polarized Raman scattering is shown. The polarized Raman signal exhibited clear orientation dependence with respect to the general film direction.

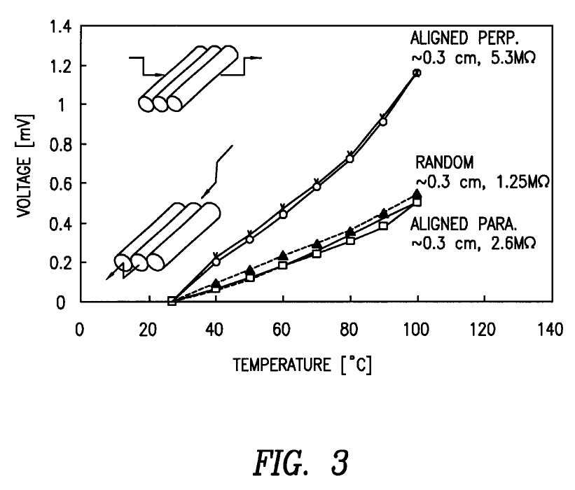

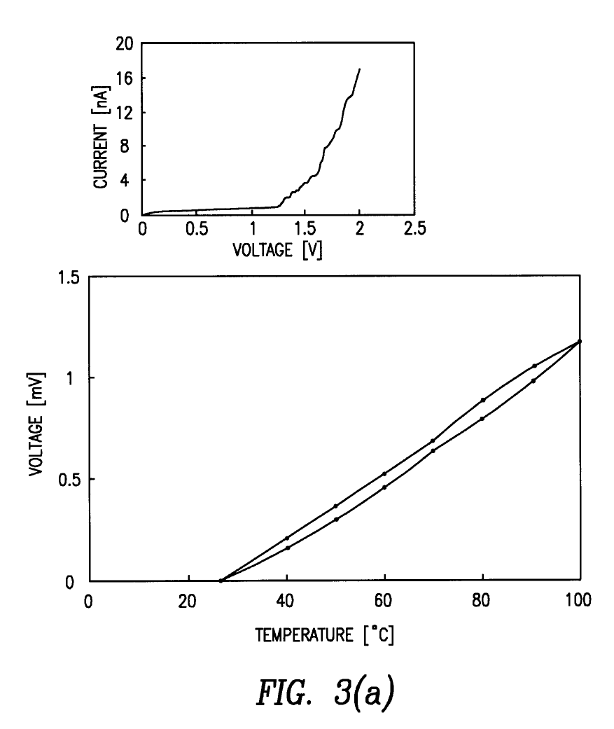

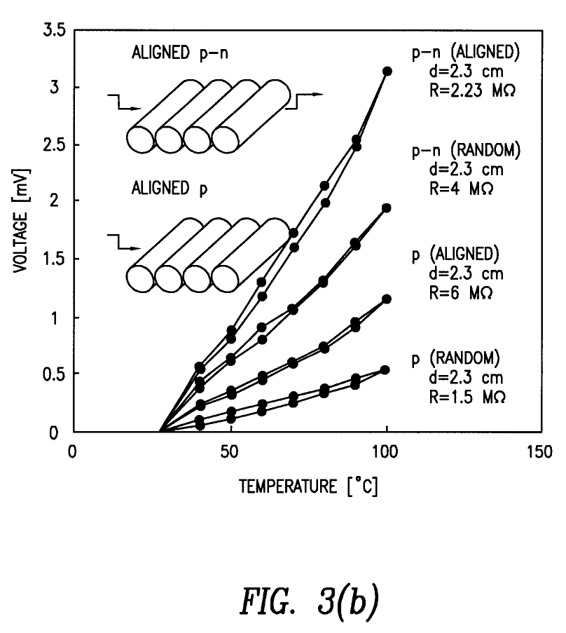

Now referring to FIG. 3, it can be seen that, with respect to the thermoelectricity developed for aligned p-type SWCNT, the developed voltage is the same for randomly oriented and coaligned SWCNT, yet larger for cross-wise aligned (crisscrossed) tubes. The insets show how current was drawn for each case; distance, resistance and orientation are indicated. The two branches for each curve indicate measurements in up and down direction. The developed TE voltage was larger when assessed cross-wisely to the direction of tubes' axis. The higher resistance in direction perpendicular to the tube axis (typically, by a factor of 2-4 compared to resistance along the tubes' axis) indicates electrical hopping mechanism between tubes.

Thermoelectricity is a widely used method for cooling and heating, sensing, heat retention, thermal management, air conditioning, and refrigeration. At its core, thermoelectricity takes advantage of materials and structures with a sustainable chemical potential difference between the hot and cold ends of a given sample. Thermoelectric (TE) power has been reported for a random array of carbon nanotubes (P. G. Collins, K. Bradley, M. Ishigami, and A. Zettl, Science 287, 1801 (2000); L. Grigorian, G. U. Sumanasekera, A. L. Loper, S. L. Fang, J. L. Allen, and P. C. Eklund, Phys. Rev. B 60, R11 309 (1999); J. Hone, B. Batlogg, Z. Benes, A. T. Johnson, and J. E. Fischer, Science 289, 1730 (2000), the entireties of which are incorporated herein by reference), and also for individual tubes (P. Kim, L. Shi, A. Majumdar, and P. L. McEuen, Phys. Rev Letts, 87, 215502 (2001)), incorporated herein by reference. TE properties of aligned and coaligned junctions made between functionalized single-wall and multiwall carbon nanotubes are evaluated herein.

FIG. 3(a) shows the corresponding TE curves for randomly oriented, side-by-side, p-n junctions made of MWCNT on glass substrates. Such configuration is superior to junctions made by layer-on-top-of-layer with a large overlapping zone. The inset shows the corresponding I-V curve.

FIG. 3(b) provides a summary for the various configurations: single p-type layers and junctions. TE for side-by-side and aligned p-n junctions measured in perpendicular direction to the tubes' axis was larger then their side-by-side randomly dispersed counterparts. The developed voltage was almost seven times larger then randomly oriented p-type only samples. Junctions formed between layers on top of each other (S. M. Mirza and H. Grebel, APL, 91, 183102 (2007)), either coaligned, cross aligned or randomly dispersed, exhibited potential difference similarly to aligned p-type films when measured across the axis of symmetry. It was apparent that favorable configurations were obtained when the contact leads are separated from the junction area by the large resistance of aligned tubes. When the junctions were formed between films on top of one another, contacts were at relatively close proximity to the junction area and the impact of local short-circuits by metallic tubes was larger. The developed voltage values in the films discussed herein are similar to that of conventional metallic thermocouples. The voltage developed between the hot and cold ends of aligned carbon nanotube films indicates preferred configurations are obtained for aligned films in perpendicular direction to the film axis of symmetry.

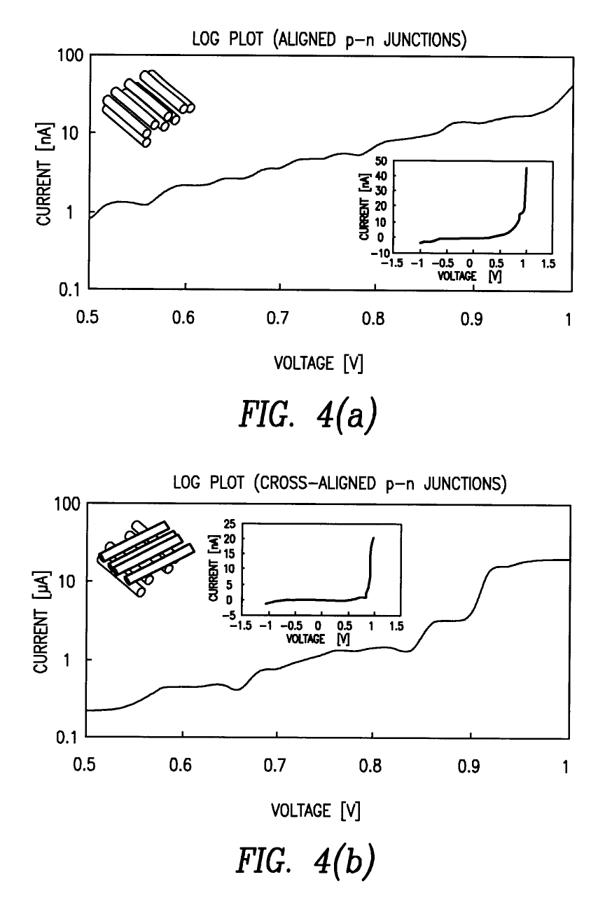

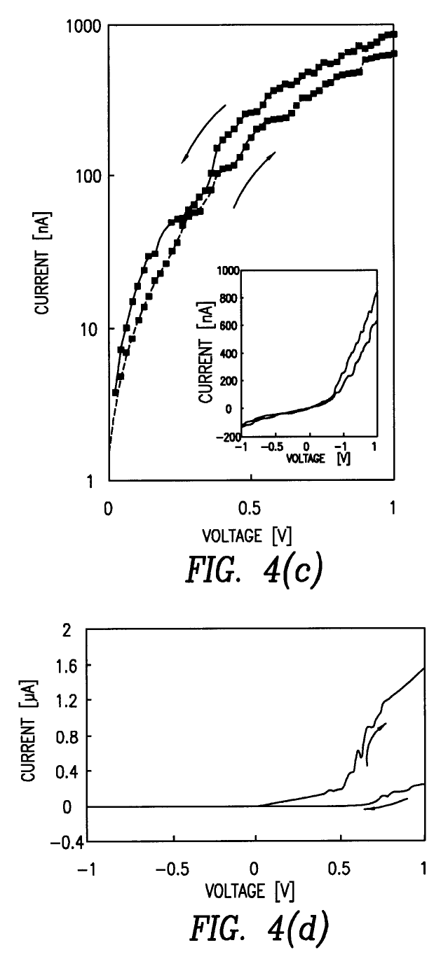

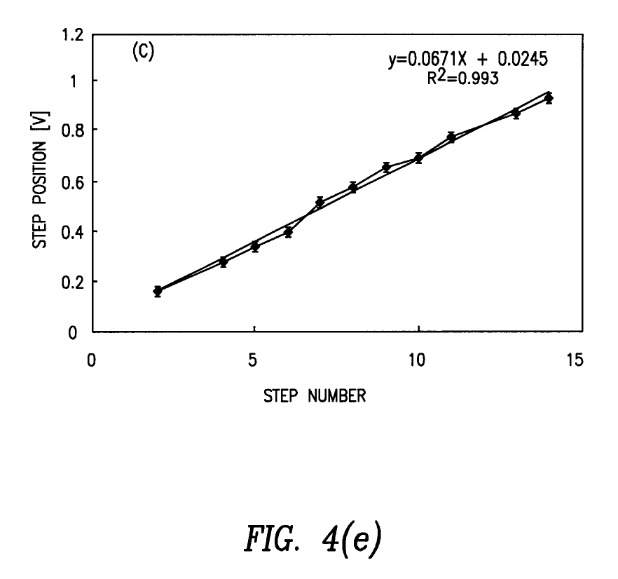

Room temperature current-voltage (I-V) measurements exhibited the difference between coaligned and cross-wisely aligned (crisscrossed) tubes. FIG. 4(a) shows the I-V curve when two films (one on top of the other) were aligned along the same direction. The junction characteristic is similar to a typical, randomly oriented p-n junction. Some statistically insignificant current fluctuations may be noted. Now referring to FIG. 4 (b), in contrast, when the p- and n-type films were oriented cross-wise with respect to one another, relatively large current stairs were exhibited.

Now referring to FIG. 4 (c) the up and down voltage ramp indicates negative differential resistance for criss-crossed p-n junctions. The relatively large leakage for the reverse bias is due to the presence of metallic tubes in the relatively thicker (˜5 microns) layers. A small negative inclination of the curve prior to each current step may be identified as well and point to negative differential resistance across the contact (Francois Leonard and J. Tersoff, PRL 85, 4767 (2000)). It should be noted that the samples' thickness was not homogeneous and the current-step amplitudes varied. In addition, not all steps were present at a given measurement point. Hysteresis (upon ramping voltage bias in up and down direction) was noted as well. FIG. 4 (d) is a graphical representation of a relatively thin (<1 micron) sample with hysteresis reversed. The occurrence of the steps was unrelated to the speed of the I-V scan or its polarity. Now referring to FIG. 2 (c), collectively, all steps appeared at well determined voltage bias values. All steps followed a straight line when plotted against the step number with a slope of 0.67 V. Most prevalent steps, appearing at least 25% of the time, were: 0.28, 0.34, 0.52, 0.66, 0.78, 0.88, ±0.02 Volts. The values of 0.52±0.02 V, 0.78±0.02 V and 0.88±0.02 V exhibited the highest frequency of occurrence (36%, 36% and 55%, respectively). Steps appeared at reverse bias as well (see below) mostly at breakdown levels. Ideality factor in the range of 1-2 (ideal diode) appeared only for the voltage range of 0.2-0.6 V. The remainder of the curve portrayed an ideality factor of 3-4. This means that the current channels were close to saturation beyond 0.6V.

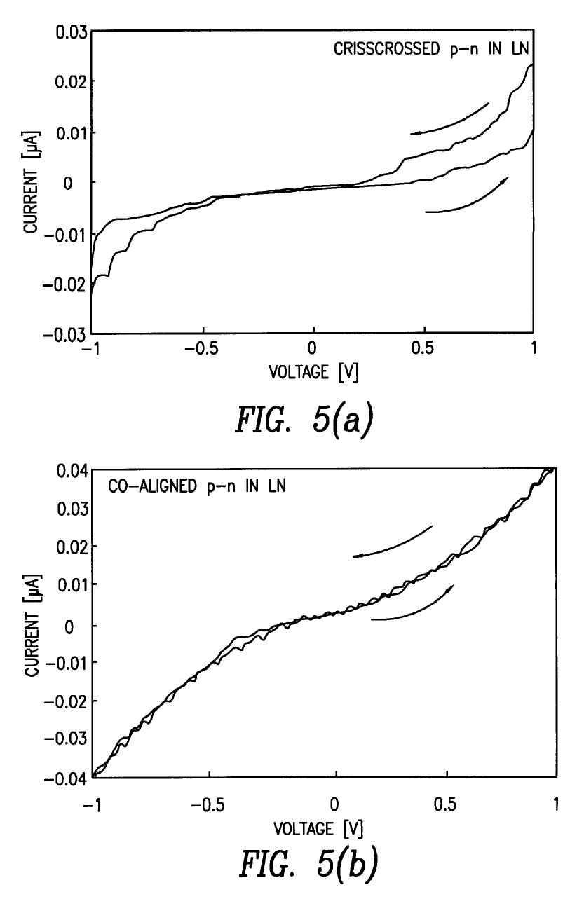

The resistance of criss-crossed junctions was two orders of magnitude larger than its corresponding value at room temperature. Now referring to FIGS. 5(a) and 5(b), which reflect I-V curves of criss-crossed and coaligned junctions immersed in liquid nitrogen in accordance with at least one aspect of the present invention, at low temperatures, current steps under reverse bias were more noticeable and the curve became more symmetrical. The effect is reversible and is still under investigation. The liquid nitrogen is inert with little content of dissolved oxygen. Yet, doping in CNT is attributed to adsorbed oxygen and local nitrogen oxidation may be a possibility under biasing, resulting in a more donor-like environment around the CNT, somewhat similar to the effect of PEI. The latter may be due to the effect of nitrogen on the effective doping of the p-type tubes. The zero voltage was noisy, within ±1 nA of the system resolution. As the sample was brought to room temperature, the curve a-symmetry was retained.

While not being limited to any single theory, the data imply that the current steps may be related to the local barriers between the p- and n-type layers. Now referring to FIG. 6, coaligned and crisscrossed layers of the same type (either only p-type or, only n-type) exhibited almost linear characteristics at room and liquid nitrogen (LN) temperatures. FIG. 6 demonstrates the ohmic contact to and from the films. Similar constructions for p-type were linear as well. Unlike a random network of tubes (see, S. Kumar, J. Y. Murthy, and M. A. Alam, PRL 95, 066802 (2005)), this diode network has a well-defined orientation and discrete manifold of (relatively narrow) energy levels across each dot-junction. The fact that the steps appear at room as well as at LN temperatures, exclude to a certain degree, percolation and as a result, the present methods focus on the local junction instead. Simple percolation process through a diode grid may be advanced by succession of diode firing. However, random diode firing would result in a monotonous DC I-V curve with ideality factor larger than 2. It is noted that energy level separation in the carbon nanotubes is rather large (on the order of 0.3-0.5 eV), larger than the voltage steps (˜0.067 eV). Electronic scattering could be related to well-defined low-energy exchange, for example local modes of phonon/polaritons (R. Martel, T. Schmidt, H. R. Shea, T. Hertel, and Ph. Avouris, APL, 73, 2447 (1998)). No special Raman line was found around 1000 cm⁻¹, but there are some IR bands in the vicinity of 800-1100 cm⁻¹ (U. J. Kim, C. A. Furtado, X. Liu, G. Chen, and P. C. Eklund, JACS, 127, 15437-15445 (2005)). The regularity of steps imply a coherent energy exchange at room temperature and it appears that three-phonon interaction is responsible for such phenomenon.

The fact that the distance between contacts could vary with little effect on the current stair position means that the effect was mainly dictated by the junction properties. Energy level separation within each tube (either metallic or semiconductive, n- or p-type) is rather large (on the order of 0.3-0.5 eV), in comparison to these voltage steps (˜0.067 eV). Periodic behavior could be related to well-defined low-energy exchange, for example local modes of phonon/polaritons (R. Martel et al., APL, 73, 2447 (1998)). We found no special Raman line around 540 cm⁻¹ (˜0.067 eV) but there are numerous IR bands in the range of 500-600 cm⁻¹. Such a plethora of energy IR bands should have resulted in an averaged and monotonous I-V curve.

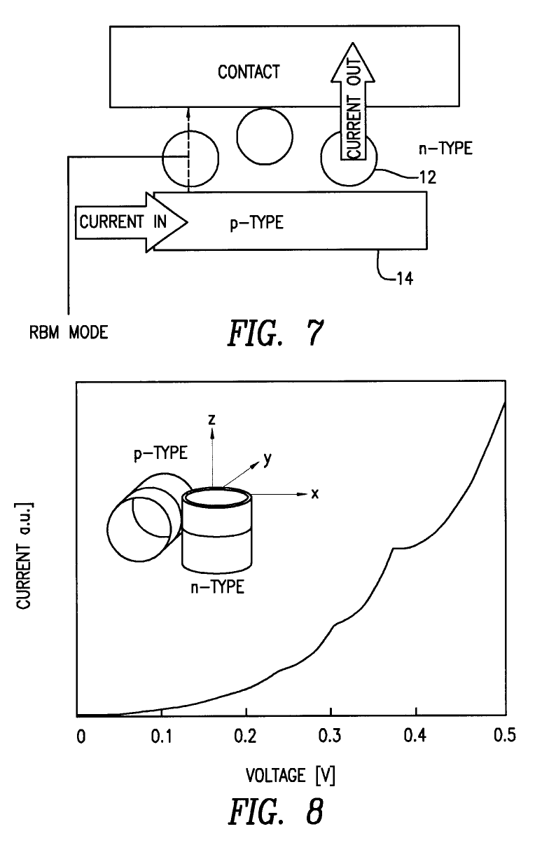

Now referring to FIG. 7, two crisscrossed nanotubes 12 and 14 with terminals are depicted. The initial and final current states are perpendicular to one another. For purposes of illustration it can be assumed that the initial current component is along the x-direction and that the second tube is aligned along the y-direction. For criss-crossed tubes, without being bound to a single theory, we postulate that the effect is due to a parabolic quantum dot contact formed between local p and n-type carbon nanotube strands (see FIG. 8). Bound states are formed across the barrier as a result of an interaction between the free carriers in one tube and the bound state of the other. Considering one dimensional case in the x-y plane; the distance between tubes is gradually changing as a function of y and varies as, ˜d+y²/2a. Here, d is the minimum distance between tubes, a is the tube radius and y=0 is placed at the contact point. Without the effect of the contact, carriers are free to move along the y-direction of the p-type tube. Periodic boundary conditions are maintained around the circumference of the n-type tube and to the lowest order, the s-like wavefunction in the n-type tube is evenly distributed along the tube circumference. The potential perturbation impressed on the free-carriers along the y-direction in the p-type tube may be approximated by a parabola and a gradual quantum dot (QD) is formed at the point of contact. Likewise, a QD is formed along the z-direction of the n-type tube at the point of contact. This perturbation is equivalent to impressing harmonic potential well in the path of the free carriers. Thermal effects would be on the order of k_{B}T/q=26 mV and therefore, would not mask transitions on the order of ˜67 mV.

This holds for coaligned junctions as well. Now referring to FIG. 4 (a), there are also shown current steps, albeit much smaller, which appear at integral bias difference-values of 0.066 V. The foregoing rationale holds for a nanojunction formed between criss-crossed and coaligned tubes alike. Yet, as the contact area between the p-and n-type tubes increases, local surface states and co-linear electronic scattering make the current a monotonous function of the bias voltage. This might be the case for relatively thick criss-crossed p-n films as well: their I-V curves were similar to coaligned or, randomly distributed junctions.

For purposes of illustration, the spring constant K and the average distance between two contacting tubes can be estimated: from the experiment, the energy difference between adjacent levels is hω=ΔE₀=0.067 eV. The electrostatic potential at the point of contact is ρₚρₙ/4πε₀x₀ with ρ being the electronic charge of the p- and n-type, respectively and ε₀ the vacuum permittivity. The latter is equal to the spring energy (1/2)Kx₀²=(1/2)mₑω₀²x₀². It can be estimated that K˜5×10⁻⁴ N/m with a distance of x₀˜6 nm between the tubes. The thickness of the polymeric sheath around each tube was estimated at 5-10 nm by use of SEM limited by a system resolution of 5 nm. Self consistency with x₀˜6 nm translates to a density of charges ρ, which is on the order of one charge per 500 atoms, somewhat lower than what was estimated for MWCNT (Vasili Perebeinos, J. Tersoff, and Phaedon Avouris, PRL 94, 086802 (2005)) yet, larger than the free carrier level of graphite (one hole per 10000 atoms).

Carrier transport is made via tunneling. The tunneling probability T for a one dimensional barrier may be given empirically as, T˜exp(−|Eₙ−eV|/C). Here, Eₙ=E₀(n+1/2) the energy levels of the bound states in the parabolic QD (F. Capasso, S. Sen, A. C. Gossard, R. A. Spah, A. L. Hutchinson and S. N. G. Chu, IEEE IEDM, Vol 33, 66-69 (1987)) and C is a characteristic constant. Metallic tubes could exhibit similar behavior as long as a barrier (such as, a Schottky barrier) is formed across the contact and charge separation occurs. As mentioned hereinbefore, the separation of energy levels in either type is well above this local perturbation and will not affect Eₙ. The current through the junction (V_{T}˜0.026 V at room temperature; η is the ideality factor), I_{D}=I₀[exp(V/ηV_{T})−1] will be given as, I=(A+BT) I_{D}; a qualitative graph is given in FIG. 8. The QD disappears when a contact is made between similar type materials since the perturbation potential, impressed on the free carriers, becomes repulsive. In addition, the contact potential is inversely proportional to the radii of the two, perpendicularly contacting strands. If the radius of curvature of each contacting strand is substantially increased then, energy level separation will be smaller than the subsequent thermal energy and the effect will be diminished. That may explain why the effect has not been observed in crisscrossed quantum wires whose diameter is d>10 nm (compared to d˜1 nm of SWCNT). Similar arguments may hold when the contact area between strands becomes large, such as, is formed between coaligned tubes. In summary, electrical properties of crisscross functionalized SWCNT reveal staircase-like I-V curves which were attributed to the formation of quantum dot at the point of contact.

The present invention may be employed in various suitable applications such as but not limited to optoelectronic and bioelectronic devices. Other suitable applications will be apparent to those having skill in the art.

While the foregoing is directed to embodiments of the present invention, other and further embodiments of the invention may be devised without departing from the basic scope thereof, and the scope thereof is determined by the claims that follow.

All references cited herein including those that follow are incorporated fully by reference.

### REFERENCES

1. J. H. Hafner, C. L. Cheung, T. H. Oosterkamp, and C. M. Lieber, J. Phys. Chem. B, 105, 744 (2001).
2. G. Fanchini, H. E. Unalan, and M. Chhowalla, Appl. Phys. Lett., 88, 191919-1 (2006).
3. J. Hone, M. C. Llaguno, N. M. Names, A. T. Johnson, J. E. Fischer, D. A. Walters, M. J. Casavant, J. Schmidt, and, R. E. Smalley, Appl. Phys. Lett., 77, 666 (2000).
4. Konstantin K. Likharev, Proc. IEEE, 87, 606 (1999).
5. M. J. Biercuk, N. Mason, J. Martin, A. Yacoby, and C. M. Marcus, PRL 94, 026801 (2005).
6. Chongwu Zhou, Jing Kong, Erhan Yenilmez, Hongjie Dai, Science, 290, 1.552 (2000).
7. Xiangfeng Duan, Yu Huang, Yi Cui, Jianfang Wang and Charles M. Lieber, Nature, 409, 66 (2001).
8. J. Liu, A. G. Rinzler, H. Dai, J. H. Hafner, R. K. Bradley, P. J. Boul, A. Lu, T. Iverson, K. Shelimov, C. B. Huffman, F. Rodriguez-Macias, Y. S. Shon, T. R. Lee, D. T. Colbert, R. E. Smalley, Science, 280, 1253 (1998).
9. Jorio, A.; Souza Filho, A. G.; Dresselhaus, G.; Dresselhaus, M. S.; Swan, A. K.; Ünlü, M. S.; Goldberg, B. B.; Pimenta, M. A.; Hafner, J. H.; Lieber, C. M.; Saito, R. Phys. Rev. B, 65, 155412 (2002).
10. P. G. Collins, K. Bradley, M. Ishigami, and A. Zettl, Science, 287, 1801 (2000).
11. L. Grigorian, G. U. Sumanasekera, A. L. Loper, S. L. Fang, J. L. Allen, and P. C. Eklund, Phys. Rev. B 60, R11 309 (1999).
12. J. Hone, B. Batlogg, Z. Benes, A. T. Johnson, and J. E. Fischer, Science 289, 1730 (2000).
13. P. Kim, L. Shi, A. Majumdar, and P. L. McEuen, Phys. Rev Letts, 87, 215502 (2001).
14. S. M. Mirza and H. Grebel, APL, 91, 183102 (2007).
15. Francois Leonard and J. Tersoff, PRL 85, 4767 (2000).
16. S. Kumar, J. Y. Murthy, and M. A. Alam, PRL 95, 066802 (2005).
17. R. Martel, T. Schmidt, H. R. Shea, T. Hertel, and Ph. Avouris, APL, 73, 2447 (1998).
18. Un Jeong Kim, Clascidia A. Furtado, Xiaoming Liu, Gugang Chen, and Peter C. Eklund, JACS, 127, 15437-15445 (2005).
19. Vasili Perebeinos, J. Tersoff, and Phaedon Avouris, PRL 94, 086802 (2005).
20. F. Capasso, S. Sen, A. C. Gossard, R. A. Spah, A. L. Hutchinson and S. N. G. Chu, IEEE IEDM, 33, 66-69 (1987).

What is claimed is:

1. A device comprising at least one n-type carbon nanotube disposed cross-wise with respect to at least one p-type carbon nanotube, the n-type and p-type carbon nanotubes forming at least one nano-junction therebetween.

2. A device in accordance with claim 1 comprising a plurality of n-type carbon nanotubes.

3. A device in accordance with claim 1 comprising a plurality of p-type carbon nanotubes.

4. A device in accordance with claim 1 comprising a plurality of n-type carbon nanotubes and a plurality of p-type carbon nanotubes.

5. A device in accordance with claim 2, the plurality of n-type carbon nanotubes forming a film.

6. A device in accordance with claim 3, the plurality of p-type carbon nanotubes forming a film.

7. A device in accordance with claim 4, the plurality of n-type carbon nanotubes forming a film and the plurality of p-type carbon nanotubes forming a film.

8. A device in accordance with claim 1, the device comprising at least one output terminal, at least one input terminal and at least one contact.

9. A device in accordance with claim 1 wherein at least one of the carbon nanotubes comprises a functionalizing agent.

10. A device in accordance with claim 1 wherein at least one of the carbon nanotubes further comprises polyvinylpyrrolidone or polyethylenimine.

11. A bioelectronic device in accordance with claim 1.

12. An optoelectronic device in accordance with claim 1.

13. A method of making a crisscrossed p-n nanojunction comprising the steps of functionalizing a carbon nanotube to create a p-type tube, functionalizing a carbon nanotube to create an n-type tube, applying an RF field to align nanotubes of a given p- or n-type, and orienting nanotubes of different types cross-wise to each other to achieve criss-crossed p-n nanojunctions.

14. A method in accordance with claim 13 comprising forming functionalized p-type carbon nanotubes into a p-type film, forming functionalized n-type carbon nanotubes into an n-type film, and orienting one of the films over the other such that the carbon nanotubes of the respective films are cross-wise to one another.

15. A method in accordance with claim 13 comprising forming a network of criss-crossed diodes.

16. A method of identifying a carbon nanotube bridge before and after interconnection.

17. A thermoelectric device in accordance with claim 1

18. A thermoelectric segmented device comprising at least one segment comprising aligned n-type or p-type SWCNT film and at least one other segment comprising n-type or p-type SWCNT film, wherein the segments are coaligned with respect to each other and interface one another along a common region.

19. A thermoelectric segmented device in accordance with claim 18 wherein the coaligned segments comprise the same type SWCNT film.
